(19) United States
(12) Patent Application Publication
(10) Pub. No.: US 2020/0274533 A1
(43) Pub. Date: Aug. 27, 2020

(54) SWING CONTROL GATE DRIVER DEVICE

(71) Applicant: MAPS, INC., SEOUL (KR)

(72) Inventors: Jong Tae HWANG, Seoul (KR); Sung Min PARK, Seoul (KR); Ki Woong JIN, Anyang-si (KR); Hyun Ick SHIN, Seoul (KR); Joon RHEE, Seoul (KR)

(73) Assignee: MAPS, INC., Seoul (KR)

(21) Appl. No.: 16/613,935

(22) PCT Filed: Feb. 21, 2018
(86) PCT No.: PCT/KR2018/002094

§ 371 Date: Nov. 15, 2019

(30) Foreign Application Priority Data
Jun. 5, 2017 (KR) 10-2017-0069752

(51) Int. Cl. H03K 17/687; H02J 50/12

(52) U.S. Cl. CPC H03K 17/687; H02J 50/12

(57) ABSTRACT

A swing regulated gate driver apparatus is provided. The swing regulated gate driver apparatus according to one embodiment includes a regulator configured to regulate a power voltage of a gate driver to a regulator output voltage at a predetermined level, and a gate driver configured to apply a variable swing output voltage between a ground voltage and the regulator output voltage to a receiver element to drive the receiver element.

### BACKGROUND

### 1. Field

The following description relates to a gate driver, and more specifically, to a controlling technology of variable swing of a gate driver.

### 2. Description of Related Art

A gate driver is an apparatus configured to drive a power switch such as a metal-oxide semiconductor field-effect transistor (MOSFET). In order to drive the MOSFET, a predetermined driving voltage should be applied to a gate terminal of the MOSFET. The MOSFET may be modeled as a capacitor when viewed from the gate terminal. A gate driver apparatus can drive the MOSFET by applying a driving voltage to the capacitor.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The following description relates to a gate driver apparatus capable of reducing driving loss.

In one general aspect, a swing regulated gate driver apparatus includes a regulator configured to regulate a power voltage of a gate driver to a regulator output voltage at a predetermined level, and a gate driver configured to apply a variable swing output voltage between a ground voltage and the regulator output voltage to a receiver element to drive the receiver element.

The regulator may regulate the regulator output voltage so that conduction loss generated from the receiver element and driving loss consumed when charging and discharging a gate-source capacitor of the receiver element may become the same.

In the regulator, the regulator may control a reference voltage thereof to regulate the power voltage of the gate driver to the regulator output voltage. In this case, the regulator may control the reference voltage so that the regulator output voltage may change in proportion to a current flowing through the receiver element.

The regulator may include a voltage distribution part configured to distribute the power voltage provided to the regulator, a controller configured to control the regulator output voltage using the power voltage distributed from the voltage distribution part, an output part configured to receive a regulator driving voltage from the controller to output the regulator output voltage to an output terminal, and a feedback part using the controller to control feedback of the regulator output voltage.

The voltage distribution part may include a first resistor connected between a regulator input node and ground, and a second resistor connected to the first resistor in series in a space between the regulator input node and the ground. The voltage distribution part may change the power voltage according to a resistance ratio between the first resistor and the second resistor to generate a reference voltage and transmit the reference voltage to the controller. The voltage distribution part may identically control the resistance ratio between the first resistor and the second resistor so that the regulator output voltage may become half of the power voltage.

The controller may include an error amp having a negative terminal to which the regulator output voltage is input and a positive terminal to which the reference voltage distributed from the voltage distribution part is input. The error amp may compare the regulator output voltage and the reference voltage which are input and control an error between the regulator output voltage and the reference voltage to control so that the regulator output voltage becomes the same as the reference voltage.

The output part may include a first MOSFET including an input connected to the regulator driving voltage applied from the controller, a first output connected to the power voltage, and a second output connected to the regulator output voltage.

The feedback part may include a first switch including an input connected to a driver input signal, a first output connected to a feedback resistor, and a second output connected to the regulator output voltage, a first capacitor of which one end is connected to ground and the other end is connected to a node between the controller and the feedback resistor, and the feedback resistor of which one end is connected to the first switch and the other end is connected to a node between the controller and the first capacitor.

The feedback part may turn off the first switch to prevent feedback of the regulator output voltage to the controller when the driver input signal is at a low level and may charge the regulator output voltage directly before the first switch is turned off in the first capacitor and provide the regulator output voltage to the controller to stabilize the regulator output voltage.

The swing regulated gate driver apparatus may further include a filter configured to stabilize a negative feedback loop of the regulator to prevent oscillation of the output voltage.

In another general aspect, a power transmitting unit includes a power amplifier including a swing regulated gate driver apparatus and a receiver element and configured to amplify wireless power using a driving frequency signal, and a transmission resonator configured to transmit the wireless power output from the power amplifier using a resonant frequency, wherein the swing regulated gate driver apparatus includes a regulator configured to regulate a power voltage of a gate driver to a regulator output voltage at a predetermined level, and a gate driver configured to apply a variable swing output voltage between a ground voltage and the regulator output voltage to the receiver element to drive the receiver element.

In still another general aspect, a power receiving unit includes a reception resonator using a resonant frequency to receive wireless power, and a rectifier including a swing regulated gate driver apparatus and a receiver element and configured to convert alternating current power received from the reception resonator to direct current power to supply a rectifier output voltage to a load, wherein the swing regulated gate driver apparatus includes a regulator configured to regulate a power voltage of a gate driver to a regulator output voltage at a predetermined level, and a gate driver configured to apply a variable swing output voltage between a ground voltage and the regulator output voltage to the receiver element to drive the receiver element.

Other features and aspects will be apparent from the following detailed description, the drawings, and the claims.

### BRIEF DESCRIPTION OF THE DRAWINGS

FIG. 1 is a circuit diagram of a general gate driver.

FIG. 2 is a graph illustrating conduction loss (Pcond) [W] and driving loss (Pdrv) [W] according to a power voltage VDD [V] in the gate driver in FIG. 1.

FIG. 3 is a circuit diagram of a swing regulated gate driver (hereinafter, referred to as SRGD) according to one embodiment of the present invention.

FIG. 4 is a detailed circuit diagram of the SRGD according to one embodiment of the present invention in FIG. 3.

FIG. 5 is a waveform view of signals when an SRGD structure in FIG. 4 is simulated.

FIG. 6 is a view of a structure of a power transmitting unit including a high speed and high efficiency power amplifier using the SRGD according to one embodiment of the present invention.

FIG. 7 is a view of a structure of a power receiving unit including a high speed and high efficiency active rectifier using an SRGD according to another embodiment of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Advantages and characteristics of the present invention, and methods of achieving the above will be apparent with reference to the accompanying drawings and embodiments which will be described later in detail. However, the present invention is not limited to the embodiments which will be disclosed later and may be implemented in various shapes. The embodiments are provided only to completely disclose the present invention, and notify scope of the present invention to those skilled in the art, and the present invention is defined only by scope of claims. The same reference numeral is referred to as the same element throughout the specification.

In descriptions of the embodiments of the present invention, when specific descriptions known functions and configurations are determined to unnecessarily obscure principle of the present invention, the detailed descriptions will be omitted, and terms which will be described later are terms determined in consideration of functions in the embodiments of the present invention, and may be changed according to intention or custom of a user, an operator, or the like. Accordingly, definitions should be made on the basis of contents throughout the specification. Here, embodiments of the present invention will be described in detail with reference to the accompanying drawings.

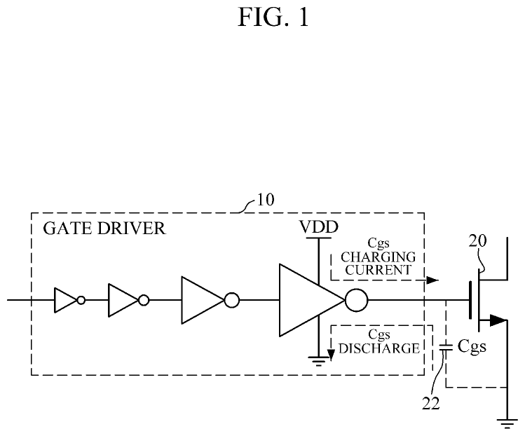

FIG. 1 is a circuit diagram of a general gate driver.

Referring to FIG. 1, a driving circuit referred to as a gate driver 10 is necessary to drive a large capacity switch which is a receiver element, for example, a MOSFET 20. As shown in FIG. 1, in the MOSFET 20, a gate-source capacitor (Cgs) 22 is equivalently present between a gate and a source. In this case, the MOSFET 20 is turned on when the gate-source capacitor (Cgs) 22 is charged, whereas the MOSFET 20 is turned off when the gate-source capacitor (Cgs) 22 is discharged. Accordingly, the gate driver 10 may serve to smoothly charge and discharge the gate-source capacitor (Cgs) 22.

Since the gate driver 10 should charge and discharge the gate-source capacitor (Cgs) 22 using a large current, the final output of the gate driver 10 generally has a large current driving capability. In FIG. 1, the current driving capability is symbolized by sizes of inverters. In a structure shown in FIG. 1, since driving time delay may be optimized and a driving capability may be improved by gradually increasing the sizes of the inverters constituting the gate driver 10, the above is one of mainly used methods.

When a power voltage of the gate driver 10 is referred to as VDD, power necessary for driving becomes a function of the power voltage VDD. Further, driving power varies according to a driving cycle. In the MOSFET 20, conduction loss occurs. Further, consumption occurs in the gate driver 10 when the gate-source capacitor (Cgs) 22 of the MOSFET 20 is charged, and consumption occurs once more when the gate-source capacitor (Cgs) 22 of the MOSFET 20 is discharged, accordingly, a total amount of the consumption may be referred to as driving loss (Pdrv) or driving power. In this case, the driving power (Pdrv) is shown as an equation which will be described later.

Pdrv=Cgs×VDD²×f [Equation 1]

As shown in Equation 1, the driving power Pdrv is proportional to the square of the power voltage VDD and proportional to a driving frequency f. Further, the driving power Pdrv is proportional to a capacitance value of the gate-source capacitor (Cgs) 22. The capacitance value of the gate-source capacitor (Cgs) 22 is determined by the used MOSFET 20 and thus is a variable that is difficult to arbitrarily change. However, the driving frequency f and the power voltage VDD are setting values that are adjustable when the driving circuit is designed. However, since the driving frequency f is usually predetermined according to an application, it is reasonable to regard only the power voltage VDD as an adjustable parameter.

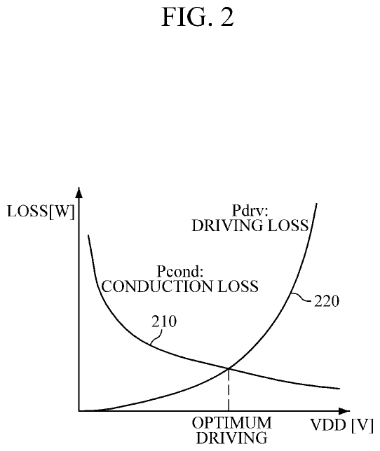

FIG. 2 is a graph illustrating conduction loss (Pcond) [W] and the driving loss (Pdrv) [W] according to the power voltage VDD [V] in the gate driver in FIG. 1. Referring to FIGS. 1 and 2, when the power voltage VDD decreases, since a resistance value of a resistance Ron of the MOSFET 20 increases, the conduction loss (Pcond) 210 increases. However, the driving loss (Pdrv) 220 decreases. The resistance Ron according to the power voltage VDD follows an equation which will be described later.

$$P c o n d ∝ R o n ∝ \frac{1}{VDD} \qquad [ Equation 2 ]$$

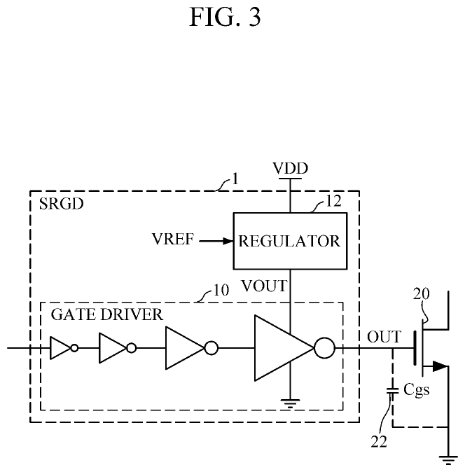

As shown in Equation 1 and Equation 2, it may be observed that the conduction loss (Pcond) 210 is inversely proportional to the power voltage VDD, while the driving loss (Pdrv) 220 is proportional to the square of the power voltage VDD. Accordingly, when the power voltage VDD is regulated, since a case in which the conduction loss (Pcond) is equal to the driving loss (Pdrv) is satisfied, optimal driving in which efficiency is optimized may be performed. For the optimal driving, the present invention proposes a circuit shown in FIG. 3.

FIG. 3 is a circuit diagram of a swing regulated gate driver (hereinafter, referred to as SRGD) according to one embodiment of the present invention.

Referring to FIG. 3, an SRGD 1 includes the gate driver 10 and a regulator 12. It can be seen that a voltage at a final stage of the gate driver 10 may be determined as an output voltage VOUT of the regulator 12 instead of the power voltage VDD. That is, the regulator 12 regulates the power voltage VDD of the gate driver 10 to the regulator output voltage VOUT, and the gate driver 10 applies a variable swing output voltage OUT between the ground voltage VDD and the regulator output voltage VOUT to a transistor which is a receiver element to drive the transistor.

The regulator output voltage VOUT according to one embodiment is changed by a reference voltage VREF of the regulator 12. As described above, when a circuit is configured, the driving loss (Pdrv) may be described like an equation to be described later.

Pdrv=Cgsλ(VOUT²×f)+Cgs×(VDD−VOUT)×VOUT×f [Equation 3]

In Equation 3, a former component of the drive loss Pdrv becomes loss of the gate driver 10 and a latter component becomes power consumption of the regulator 12. When the regulator output voltage VOUT is set to the power voltage VDD/2, the driving loss (Pdrv) is changed to Equation 4 to be described later.

Pdrv=½Cgs×VDD²×f [Equation 4]

That is, the driving loss is halved in comparison with conventional driving. However, since driving swing of the MOSFET decreases, the conduction loss increases. Although it depends on the type of the MOSFET, when the driving voltage is halved, the resistance value of the resistance Ron of the MOSFET 20 tends to increase in a range of roughly 20 to 30%. That is, the conduction loss increases in a range of 20 to 30%. However, since the driving loss decreases by 50%, total loss is improved in a range of 20 to 30%. Further, as shown in FIG. 2, optimum driving may be performed by changing the regulator output voltage VOUT through regulation of the reference voltage VREF.

Generally, when the MOSFET 20 drives a small current, the conduction loss is not large even when the resistance value of the resistance Ron is large. Accordingly, when the reference voltage VREF is regulated so that the regulator output voltage VOUT is changed in proportion to a current which flows through the MOSFET 20, active control may be performed so that efficiency may be improved according to the condition when the current of the MOSFET is large or small.

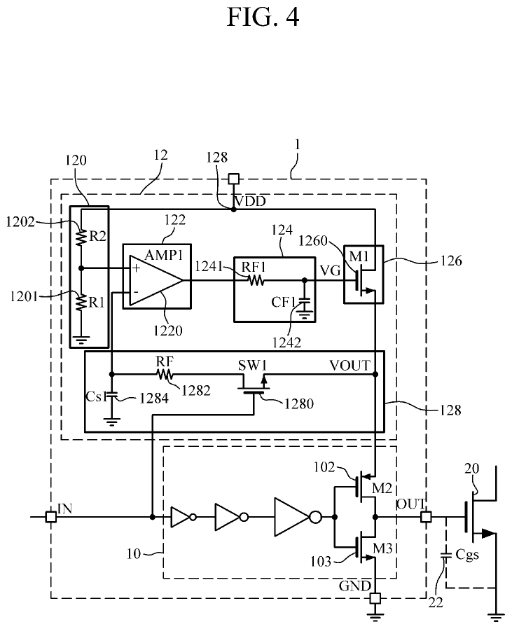

FIG. 4 is a detailed circuit diagram of the SRGD according to one embodiment of the present invention in FIG. 3.

Referring to FIG. 4, the SRGD 1 includes the gate driver 10 and the regulator 12. The gate driver 10 may include a plurality of inverters. The regulator 12 may include a voltage distribution part 120, a controller 122, a filter 124, an output part 126, and a feedback part 128.

The inverter constituting the gate driver 10 may include a high-side switch and a low-side switch, and in FIG. 4, a second MOSFET (M2) 102 which is a high-side switch of the inverter of the final stage, and a third MOSFET (M3) 103 which is a low-side switch of the inverter of the final stage are shown. The second MOSFET (M2) 102 includes an input connected to a previous inverter, a first output connected to the regulator output voltage VOUT, and a second output connected to the driver output voltage OUT. The third MOSFET (M3) 103 includes an input connected to the previous inverter, a first output connected to the driver output voltage OUT, and a second output connected to ground GND.

The voltage distribution part 120 distributes the power voltage VDD provided to the input node 128 of the regulator 12. The voltage distribution part 120 according to one embodiment includes a first resistor (R1) 1201 and a second resistor (R2) 1202 serially connected to each other between the input node 128 and the ground. The voltage distribution part 120 changes the power voltage VDD according to a resistance rate between the first resistor (R1) 1201 and the second resistor (R2) 1202 to generate the reference voltage VREF and transmits the reference voltage VREF to the controller 122. When R1 is equal to R2, the regulator output voltage VOUT becomes half of the power voltage VDD.

The controller 122 controls the output voltage VOUT of the regulator 12. The controller 122 may include an error amp (AMP1) 1220. In the error amp (AMP1) 1220, the regulator output voltage VOUT is input to a negative terminal and the reference voltage VREF distributed from the voltage distribution part 120 is input to a positive terminal, and the regulator output voltage VOUT and the reference voltage VREF are compared and an error between the regulator output voltage VOUT and the reference voltage VREF is controlled so that the regulator output voltage VOUT becomes the same as the reference voltage VREF.

The output part 126 receives a driving voltage VG from the controller 122 to provide the regulator output voltage VOUT to an output terminal. The output part 126 may include a first MOSFET (M1) 1260 as an output transistor. The first MOSFET (M1) 1260 includes an input connected to the regulator driving voltage VG, a first output connected to the power voltage VDD, and a second output connected to the regulator output voltage VOUT.

The filter 124 serves to stabilize a negative feedback loop of the regulator 12 to prevent oscillation of the regulator output voltage VOUT. To this end, the filter 124 may include a resistor (RF1) 1241 and a capacitor (CF1) 1242.

The feedback part 128 controls feedback of the regulator output voltage VOUT to the controller 122. For example, feedback of the regulator output voltage VOUT to the error amp (AMP1) 1220 is controlled. The feedback part 128 may include a first switch (SW1) 1280, a feedback resistor 1282, and a first capacitor (Cs1) 1284. The first switch (SW1) 1280 includes an input connected to an input signal IN of the gate driver 10, a first output connected to the feedback resistor 1282, and a second output connected to the regulator output voltage VOUT. In the first capacitor (Cs1) 1284, one end is connected to the ground, and the other end is connected to a node between the error amp (AMP1) 1220 and the feedback resistor 1282. In the feedback resistor 1282, one end is connected to the first switch (SW1) 1280, and the other end is connected to a node between the error amp (AMP1) 1220 and the first capacitor (Cs1) 1284.

The first switch (SW1) 1280 and the first capacitor (Cs1) 1284 of the feedback part 128 according to one embodiment perform sampling and holding operations. When the input signal IN of the gate driver 10 is at a high level, the first switch (SW1) 1280 is also turned on. Accordingly, the regulator output voltage VOUT is provided to a negative terminal of the error amp (AMP1) 1220, and the error amp (AMP1) 1220 drives the first MOSFET (M1) 1260 so that voltages of the positive terminal and the negative terminal become the same. When the input signal IN is at the high level, the second MOSFET (M2) 102 at the final stage of the gate driver 10 is also turned on. When the input signal IN is at a low level, the second MOSFET (M2) 102 is turned off and the third MOSFET (M3) 103 is turned on.

When the input signal IN is at the low level without the sampling and holding operations, since the load of the first MOSFET (M1) 1260 suddenly disappears, the regulator output voltage VOUT sharply increases. Since the regulator output voltage VOUT increases, the error amp (AMP1) 1220 lowers the driving voltage VG of the first MOSFET (M1) 1260 to lower the regulator output voltage VOUT as much as possible. Accordingly, the driving voltage VG becomes a low voltage close to the ground. When the input signal IN becomes the high level again, since the driving voltage VG is low, the first MOSFET (M1) 1260 may not smoothly supply power. Although the driving voltage VG is restored and thus sufficient power is supplied as time goes by, when the input signal IN repeatedly becomes the high level and the low level at a very quick frequency, normally forming the regulator output voltage VOUT is difficult. Accordingly, when the input signal IN is at the low level, the first switch (SW1) 1280 is turned off to prevent the feedback of the regulator output voltage VOUT to the error amp (AMP1) 1220. Alternatively, since the regulator output voltage VOUT directly before the first switch (SW1) 1280 is turned off is charged in the first capacitor (Cs1) 1284 and provided to the error amp (AMP1) 1220, the error amplifier (AMP1) 1220 misunderstands as being well controlled, and thus the driving voltage VG is not controlled. Accordingly, when the input signal IN becomes the high level again, since the first switch (SW1) 1280 is in a state of directly before being turned off, power may be quickly supplied. In order to stabilize the regulator output voltage VOUT without the circuit, a large capacitor should be connected to the regulator output voltage VOUT. The provided circuit stabilizes the regulator output voltage VOUT without using a large capacitor to allow quick driving of the gate driver.

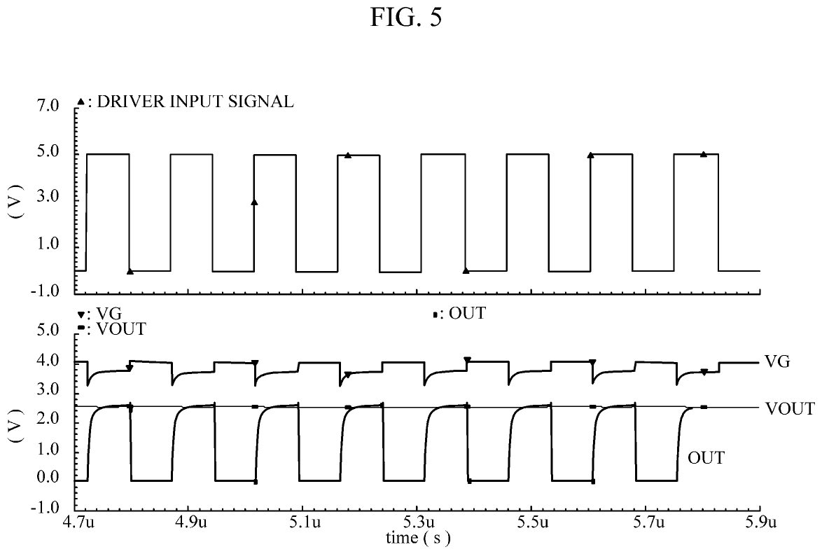

FIG. 5 is a waveform view of signals when an SRGD structure in FIG. 4 is simulated.

In simulation in FIG. 5, a driving frequency is assumed to be 6.78 MHz. Referring to FIGS. 4 and 5, although the driving frequency is 6.78 MHz and thus is very quick, the regulator output voltage VOUT is in a stable state without being influenced due to a change of the driver input signal IN. The gate driver 10 outputs the variable swing output voltage OUT which is between the ground voltage VDD and the regulator output voltage VOUT. Since the driving voltage VG of the regulator 12 is almost unchanged, the regulator 12 becomes a circuit capable of quickly supplying the power and operating without a large output capacitor.

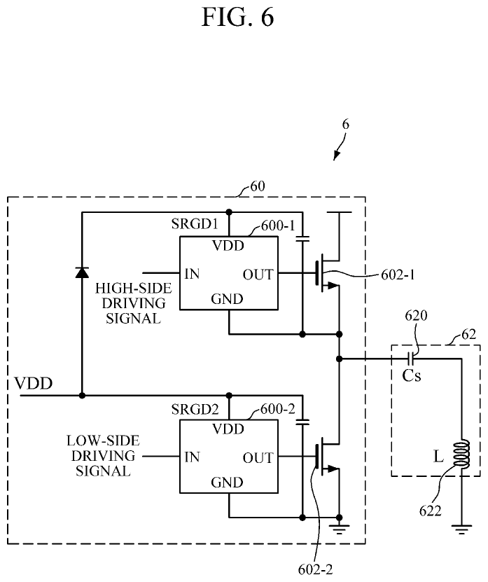

FIG. 6 is a view of a structure of a power transmitting unit including a high speed and high efficiency power amplifier using the SRGD according to one embodiment of the present invention.

Referring to FIG. 6, a power transmitting unit (PTU) 6 includes a power amplifier 60 and a transmission resonator 62.

The power amplifier 60 amplifies wireless power using a driving frequency signal. The transmission resonator 62 constitutes a resonant tank and transmits the wireless power output from the power amplifier 60 using a resonant frequency of the resonant tank. The resonant tank of the transmission resonator 62 may include a capacitor (Cs) 620 and an inductor (L) 622 which serves as an antenna.

The power amplifier 60 according to one embodiment includes a plurality of SRGDs and a plurality of switching elements. Each of the SRGDs receives a driving signal and outputs a signal for driving the transistor which is the receiver element. For example, as shown in FIG. 6, the high side includes an SRGD1 600-1 configured to receive a high-side driving signal as the input signal IN, and a first MOSFET 602-1 configured to receive a high-side output voltage OUT to be driven, and the low side includes an SRGD2 600-2 configured to receive a low-side driving signal as the input signal IN, and a second MOSFET 602-2 configured to receive a low-side output voltage OUT to be driven

As described above with reference to FIGS. 3 and 4, each of the SRGDs includes a regulator and a gate driver. The regulator regulates the power voltage VDD of the gate driver to the regulator output voltage VOUT at a predetermined level. The gate driver applies the variable swing output voltage OUT between the ground voltage VDD and the regulator output voltage VOUT to the receiver element to drive the receiver element.

In FIG. 6, although the power amplifier is limited to Class-D, the power amplifier may be replaced with a power amplifier of Class-Aft Class-B, or the like. FIG. 6 illustrates a circuit usable in a power transmitting unit of a wireless charging system using a driving frequency, for example, usable in a power transmitting unit of an A4WP wireless charging system using a driving frequency of 6.78 MHz.

The power amplifier 60 generates an alternating current signal driven at a driving frequency, for example, a frequency of 6.78 MHz, and applies the alternating current signal to the transmission resonator 62 by turning on the MOSFETs 602-1 and 602-2 at upper and lower sides to allow the transmission resonator 62 to transmit the wireless power. In an A4WP manner using a driving frequency of 6.78 MHz, since the driving frequency is very high, gate driving power becomes very high. However, when the provided manner is used, power consumption may be reduced by 20 to 30% in comparison with a conventional manner.

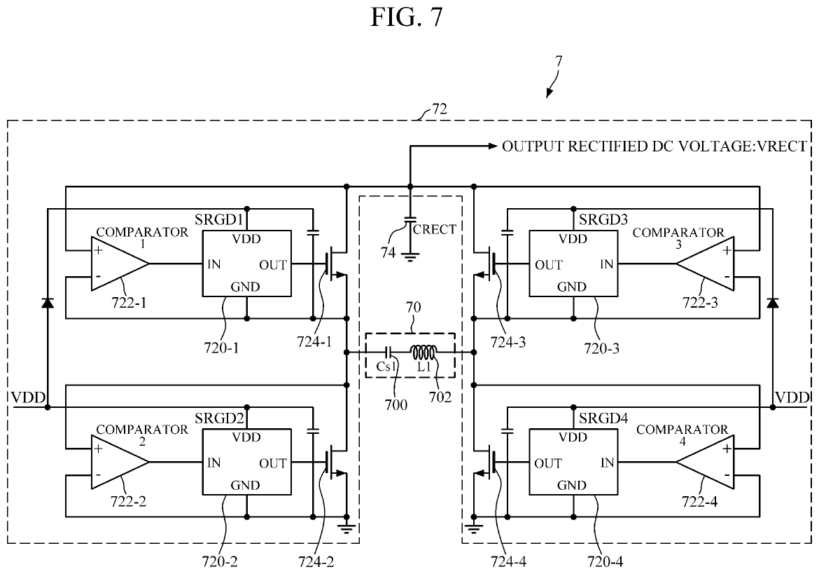

FIG. 7 is a view of a structure of a power receiving unit including a high speed and high efficiency active rectifier using an SRGD according to another embodiment of the present invention.

Referring to FIG. 7, an active rectifier capable of being operated at high speed using the SRGD may be implemented. Referring to FIG. 7, a power receiving unit (PRU) 7 includes a reception resonator 70 and a rectifier 72.

The reception resonator 70 constitutes a resonant tank and receives wireless power using a resonant frequency of the resonant tank. The resonant tank may include a capacitor (Cs1) 700 and an inductor (L1) 702 which serves as an antenna. The rectifier 72 converts alternating current power received from the reception resonator 70 to direct current power to supply a rectifier output voltage to a load.

The rectifier 72 according to the embodiment includes a plurality of SRGDs, a plurality of comparators, and a plurality of switching elements. For example, as shown in FIG. 7, the rectifier 72 includes first to fourth SRGDs 720-1, 720-2, 720-3, and 720-4, first to fourth comparators 722-1, 722-2, 722-3, and 722-4 and first to fourth MOSFETs 724-1, 724-2, 724-3, and 724-4 which are receiver elements. The first to fourth SRGDs 720-1, 720-2, 720-3, and 720-4 respectively drive the first to fourth MOSFETs 724-1, 724-2, 724-3, and 724-4.

As described above with reference to FIGS. 3 and 4, each of the SRGDs includes a regulator and a gate driver. The regulator regulates a power voltage VDD of the gate driver to a regulator output voltage VOUT at a predetermined level. The gate driver applies a variable swing output voltage OUT between the ground voltage VDD and the regulator output voltage VOUT to the receiver element to drive the receiver element.

Since output of the rectifier 72 is a rectified voltage, a capacitor (CRECT) 74 may be used to convert the output of the rectifier 72 to a direct current voltage. The power receiving unit 7 drives a load after converting the direct current voltage VRECT generated by the capacitor (CRECT) 74 into a voltage suitable for the load using a DC-DC converter.

With reference to FIG. 7, in a case of the active rectifier 72 using the provided SRGDs, since driving loss may be reduced, high rectifying efficiency may be satisfied when a high frequency alternating current signal is rectified.

According to one embodiment, when a switching element is driven at high speed, increasing driving loss can be reduced. When the driving loss increases, since efficiency decreases and the temperature of a system increases, a circuit becomes an inefficient and unreliable circuit. To this end, a swing regulated gate driver apparatus capable of controlling a driving voltage of the switching element can be provided to reduce the driving loss to solve the above-described problem.

So far, the present invention has been viewed with reference to the embodiments. Those skilled in the art may understand that the present invention may be modified without departing from an intrinsic characteristic of the present invention. Accordingly, the disclosed embodiments should be considered from a descriptive perspective instead of a limited perspective. A scope of the present invention is shown in the claims instead of the above descriptions, and differences within the scope should be understood to be included in the present invention.

What is claimed is:

1. A swing regulated gate driver apparatus comprising:
a regulator configured to regulate a power voltage of a gate driver to a regulator output voltage at a predetermined level; and
a gate driver configured to apply a variable swing output voltage between a ground voltage and the regulator output voltage to a receiver element to drive the receiver element.

2. The swing regulated gate driver apparatus of claim 1, wherein the regulator regulates the regulator output voltage so that conduction loss generated from the receiver element and driving loss consumed when charging and discharging a gate-source capacitor of the receiver element become the same.

3. The swing regulated gate driver apparatus of claim 1, wherein the regulator controls a reference voltage thereof to regulate the power voltage of the gate driver to the regulator output voltage.

4. The swing regulated gate driver apparatus of claim 3, wherein the regulator controls the reference voltage so that the regulator output voltage changes in proportion to a current flowing through the receiver element.

5. The swing regulated gate driver apparatus of claim 1, wherein the regulator includes:
a voltage distribution part configured to distribute the power voltage provided to the regulator;
a controller configured to control the regulator output voltage using the power voltage distributed from the voltage distribution part;
an output part configured to receive a regulator driving voltage from the controller to output the regulator output voltage to an output terminal; and
a feedback part using the controller to control feedback of the regulator output voltage.

6. The swing regulated gate driver apparatus of claim 5, wherein the voltage distribution part includes a first resistor connected between a regulator input node and ground, and a second resistor connected to the first resistor in series in a space between the regulator input node and the ground,
wherein the voltage distribution part changes the power voltage according to a resistance ratio between the first resistor and the second resistor to generate a reference voltage and transmits the reference voltage to the controller.

7. The swing regulated gate driver apparatus of claim 6, wherein the voltage distribution part identically controls the resistance ratio between the first resistor and the second resistor so that the regulator output voltage becomes half of the power voltage.

8. The swing regulated gate driver apparatus of claim 5, wherein the controller includes an error amp having a negative terminal to which the regulator output voltage is input and a positive terminal to which the reference voltage distributed from the voltage distribution part is input, wherein the error amp compares the regulator output voltage and the reference voltage which are input and controls an error between the regulator output voltage and the reference voltage to control so that the regulator output voltage becomes the same as the reference voltage.

9. The swing regulated gate driver apparatus of claim 5, wherein the output part includes a first MOSFET including an input connected to the regulator driving voltage applied from the controller, a first output connected to the power voltage, and a second output connected to the regulator output voltage.

10. The swing regulated gate driver apparatus of claim 5, wherein the feedback part includes:
a first switch including an input connected to a driver input signal, a first output connected to a feedback resistor, and a second output connected to the regulator output voltage;
a first capacitor of which one end is connected to ground and the other end is connected to a node between the controller and the feedback resistor; and
the feedback resistor of which one end is connected to the first switch and the other end is connected to a node between the controller and the first capacitor.

11. The swing regulated gate driver apparatus of claim 10, wherein the feedback part turns off the first switch to prevent feedback of the regulator output voltage to the controller when the driver input signal is at a low level, and charges the regulator output voltage directly before the first switch is turned off in the first capacitor and provides the regulator output voltage to the controller to stabilize the regulator output voltage.

12. The swing regulated gate driver apparatus of claim 5, further comprising a filter configured to stabilize a negative feedback loop of the regulator to prevent oscillation of the output voltage.

13. A power transmitting unit comprising:
a power amplifier including a swing regulated gate driver apparatus and a receiver element and configured to amplify wireless power using a driving frequency signal; and
a transmission resonator configured to transmit the wireless power output from the power amplifier using a resonant frequency,
wherein the swing regulated gate driver apparatus includes a regulator configured to regulate a power voltage of a gate driver to a regulator output voltage at a predetermined level, and a gate driver configured to apply a variable swing output voltage between a ground voltage and the regulator output voltage to the receiver element to drive the receiver element.

14. A power receiving unit comprising:
a reception resonator configured to receive wireless power using a resonant frequency; and
a rectifier including a swing regulated gate driver apparatus and a receiver element and configured to convert alternating current power received from the reception resonator to direct current power to supply a rectifier output voltage to a load,
wherein the swing regulated gate driver apparatus includes a regulator configured to regulate a power voltage of a gate driver to a regulator output voltage at a predetermined level, and a gate driver configured to apply a variable swing output voltage between a ground voltage and the regulator output voltage to the receiver element to drive the receiver element.
